(19) United States
(12) Patent Application Publication
(10) Pub. No.: US 2015/0263050 A1
(43) Pub. Date: Sep. 17, 2015

(54) Pixel Structure and Manufacturing Method thereof

(71) Applicant: AU Optronics Corporation, Hsin-Chu (TW)

(72) Inventors: Wen-Yi HSU, HSIN-CHU (TW); Maw-Song CHEN, HSIN-CHU (TW); Kuo-Yu HUANG, HSIN-CHU (TW)

(73) Assignee: AU Optronics Corporation, Hsin-Chu (TW)

(21) Appl. No.: 14/277,174

(22) Filed: May 14, 2014

(30) Foreign Application Priority Data
Mar. 12, 2014 (TW) 103108685

(51) Int. Cl. H01L 27/12; H01L 29/786; H01L 29/66; H01L 29/16; H01L 29/04

(52) U.S. Cl. CPC H01L 27/1288; H01L 27/1218; H01L 27/124; H01L 27/1222; H01L 29/16; H01L 29/04; H01L 29/66765; H01L 29/78678; H01L 29/78669

(57) ABSTRACT

A pixel structure includes a gate electrode, a gate dielectric layer, a silicon channel layer, a silicon source ohmic contact layer, a silicon drain ohmic contact layer, a source auxiliary ohmic contact layer, a drain auxiliary ohmic contact layer, a transparent conductive portion, a transparent pixel electrode, a source electrode, and a drain electrode. The silicon channel layer is disposed on the gate dielectric layer and above the gate electrode. The silicon source ohmic contact layer, the source auxiliary ohmic contact layer, the transparent conductive portion, and the source electrode are disposed on the silicon channel layer in sequence. The silicon drain ohmic contact layer and the drain auxiliary ohmic contact layer are disposed on the silicon channel layer in sequence. At least a portion of the transparent pixel electrode is disposed between the drain electrode and the drain auxiliary ohmic contact layer.

### RELATED APPLICATIONS

This application claims priority to Taiwan Application Serial Number 103108685, filed Mar. 12, 2014, which is herein incorporated by reference.

### BACKGROUND

1. Field of Invention

The present invention relates to a pixel structure. More particularly, the present invention relates to a pixel structure that saves photomask.

2. Description of Related Art

Due to generalization and popularization of display panels, the semiconductor industry is constantly seeking ways to produce high quality displays while reducing the manufacture cost. During the manufacturing process of a display device, the pixel structure can use multiple photomasks to define a desired deposit or removal region, thereby forming a patterned layer structure. However, how to reduce the resistance between the silicon semi-channel layer and the transparent conductive electrode to enhance the display quality is currently one of the problems that the industry thrives to solve. Furthermore, since the display device is manufactured through the use of multiple photomasks. Therefore, the technology to decrease the photomasks is one effective way to improve the manufacturing of a display device. However, how to reduce the number of uses of a photomask (which directly reduces the manufacturing cost) is currently one of the problems the industry thrives to solve.

### SUMMARY

The invention provides a pixel structure that can save photomask and manufacture cost.

One aspect of the present invention is to provide a pixel structure disposed on the substrate. The pixel structure includes a gate electrode, gate dielectric layer, silicon channel layer, silicon source ohmic contact layer, silicon drain ohmic contact layer, source auxiliary ohmic contact layer, drain auxiliary ohmic contact layer, transparent conductive portion, transparent pixel electrode, source electrode and drain electrode. The gate electrode is disposed on the substrate. The gate dielectric layer covers the gate electrode and the substrate. The silicon channel layer is disposed on the gate dielectric layer, and disposed above the gate electrode. The silicon source ohmic contact layer and the silicon drain ohmic contact layer are separately disposed on the silicon channel layer. The source auxiliary ohmic contact layer and the drain auxiliary ohmic contact layer are separately disposed on the silicon source ohmic contact layer and the silicon drain ohmic contact layer. The transparent conductive portion is disposed on the source auxiliary ohmic contact layer. At least a portion of the transparent pixel electrode is disposed on the drain auxiliary ohmic contact layer. The source electrode is disposed on the transparent conductive portion. The drain electrode is disposed on the transparent pixel electrode, and disposed above the drain auxiliary ohmic contact layer.

In one or more embodiments, the materials for the source auxiliary ohmic contact layer and the drain auxiliary ohmic contact layer are metals.

In one or more embodiments, the materials for the silicon channel layer are amorphous silicon, microcrystalline silicon, polycrystalline silicon or epitaxial silicon.

In one or more embodiments, the materials for the silicon source ohmic contact layer and the silicon drain ohmic contact layer are N-type doped silicon.

In one or more embodiments, the pixel structure further includes a gate line and a data line. The gate line is disposed between the substrate and the gate dielectric layer and electrically connected to the gate electrode. The data line is disposed on the gate dielectric layer and electrically connected to the source electrode.

In one or more embodiments, the pixel structure further includes a passivation layer and a common electrode. The passivation layer at least covers the source electrode, the drain electrode, the silicon channel layer and the transparent pixel electrode. The common electrode is disposed on the passivation layer. The common electrode and the transparent pixel electrode overlap, and the common electrode has a plurality of openings.

In one or more embodiments, the pixel structure further includes a common electrode disposed between the substrate and the gate dielectric layer, and disposed beneath the transparent pixel electrode, and the common electrode and the transparent pixel electrode overlap.

In one or more embodiments, the transparent pixel electrode has a plurality of openings.

Another aspect of the present invention is to provide a pixel structure disposed on the substrate. The pixel structure includes a gate electrode, gate dielectric layer, silicon channel layer, silicon source ohmic contact layer, silicon drain ohmic contact layer, source auxiliary ohmic contact layer, drain auxiliary ohmic contact layer, transparent conductive portion, transparent pixel electrode, source electrode, drain electrode and common electrode. The gate electrode is disposed on the substrate. The gate dielectric layer covers the gate electrode and the substrate. The silicon channel layer is disposed on the gate dielectric layer, and disposed above the gate electrode. The silicon source ohmic contact layer and the silicon drain ohmic contact layer are separately disposed on the silicon channel layer. The source auxiliary ohmic contact layer and the drain auxiliary ohmic contact layer are separately disposed on the silicon source ohmic contact layer and the silicon drain ohmic contact layer. The transparent conductive portion is disposed on the source auxiliary ohmic contact layer. At least a portion of the transparent pixel electrode is disposed on the drain auxiliary ohmic contact layer. The source electrode is disposed on the transparent conductive portion. The drain electrode is disposed on the transparent pixel electrode, and disposed above the drain auxiliary ohmic contact layer. The common electrode is disposed on the substrate, and the common electrode and the transparent pixel electrode overlap.

A further aspect of the present invention is to provide a manufacturing method for a pixel structure which includes forming a gate electrode on a substrate; sequentially forming a gate dielectric layer, a silicon semiconductor layer, a silicon ohmic contact layer and an auxiliary ohmic contact layer covering the gate electrode and the substrate; sequentially removing a portion of the auxiliary ohmic contact layer, the silicon ohmic contact layer and the silicon semiconductor layer to form a patterned auxiliary ohmic contact layer, a patterned silicon ohmic contact layer and a silicon channel layer above the gate electrode; sequentially forming a transparent conductive material layer and a metal layer covering the gate dielectric layer and the patterned auxiliary ohmic contact layer; removing parts of the metal layer to form a source electrode and a drain electrode separated from each other on the patterned auxiliary ohmic contact layer, and removing parts of the transparent conductive material layer to form a transparent pixel electrode and a transparent conductive portion separated from each other, at least a portion of the transparent pixel electrode is formed between the drain electrode and the patterned auxiliary ohmic contact layer, and the transparent conductive portion is formed between the source electrode and the patterned auxiliary ohmic contact layer; removing parts of the patterned auxiliary ohmic contact layer to respectively form a source auxiliary ohmic contact layer and a drain auxiliary ohmic contact layer below the source electrode and the drain electrode; removing parts of the patterned silicon ohmic contact layer to respectively form a silicon source ohmic contact layer and a silicon drain ohmic contact layer below the source auxiliary ohmic contact layer and the drain auxiliary ohmic contact layer.

In one or more embodiments, removing parts of the metal layer and the transparent conductive material layer includes forming a photoresist layer covering the metal layer; using a halftone photomask process to pattern the photoresist layer to form a patterned photoresist layer; using the patterned photoresist layer as a photomask to remove the exposed metal layer and expose parts of the transparent conductive material layer below the metal layer to form a source electrode, a transparent conductive portion and a transparent pixel electrode; removing another part of the photoresist layer to expose another part of the metal layer; using the remaining patterned photoresist layer as a photomask to remove another part of the metal layer to form a drain electrode, and expose the transparent pixel electrode.

In one or more embodiments, the materials for the auxiliary ohmic contact layer are metals.

In one or more embodiments, the materials for the ohmic contact layer are N-type doped silicon.

In one or more embodiments, the manufacturing method further includes forming a gate line between the substrate and the gate dielectric layer; and forming a data line on the gate dielectric layer.

In one or more embodiments, the manufacturing method further includes forming a gate electrode pad between the substrate and the gate dielectric layer; forming a data pad on the gate dielectric layer; forming a passivation layer to at least cover the source electrode, the drain electrode, the silicon channel layer, the transparent pixel electrode and the data pad; forming a first contact hole in the passivation layer to expose at least a part of the data pad; forming a second contact hole in the passivation layer, and forming a third contact hole in the gate dielectric layer, together the second contact hole and the third contact hole expose at least a part of the gate electrode pad; forming an electrode layer on the passivation layer, and the electrode layer is electrically connected to the data pad through the first contact hole, and electrically connected to the gate electrode pad through the second contact hole and the third contact hole; patterning the electrode layer to form a common electrode above the transparent pixel electrode, forming a gate electrode contact pad above the gate electrode pad, and forming a data contact pad above the data pad.

In one or more embodiments, patterning the electrode layer further includes forming a plurality of openings in the common electrode.

In one or more embodiments, the manufacturing method further includes forming a common electrode between the substrate and the gate dielectric layer.

In one or more embodiments, the manufacturing method further includes forming a plurality of openings in the transparent pixel electrode.

### BRIEF DESCRIPTION OF THE DRAWINGS

The invention can be more fully understood by reading the following detailed description of the embodiment, with reference made to the accompanying drawings as follows:

FIGS. 1 to 9 illustrate sectional views of the manufacturing process of a pixel structure according to the first embodiment of the present invention.

FIG. 10 illustrates a top schematic view of a pixel structure according to the first embodiment of the present invention.

FIGS. 11 to 20B illustrate sectional views of the manufacturing process of a pixel structure according to the second embodiment of the present invention.

FIG. 21 illustrates a top schematic view of a pixel structure according to the second embodiment of the present invention.

FIGS. 22 to 30 illustrate sectional views of the manufacturing process of a pixel structure according to the third embodiment of the present invention.

FIG. 31 illustrates a top schematic view of a pixel structure according to the third embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

### First Embodiment

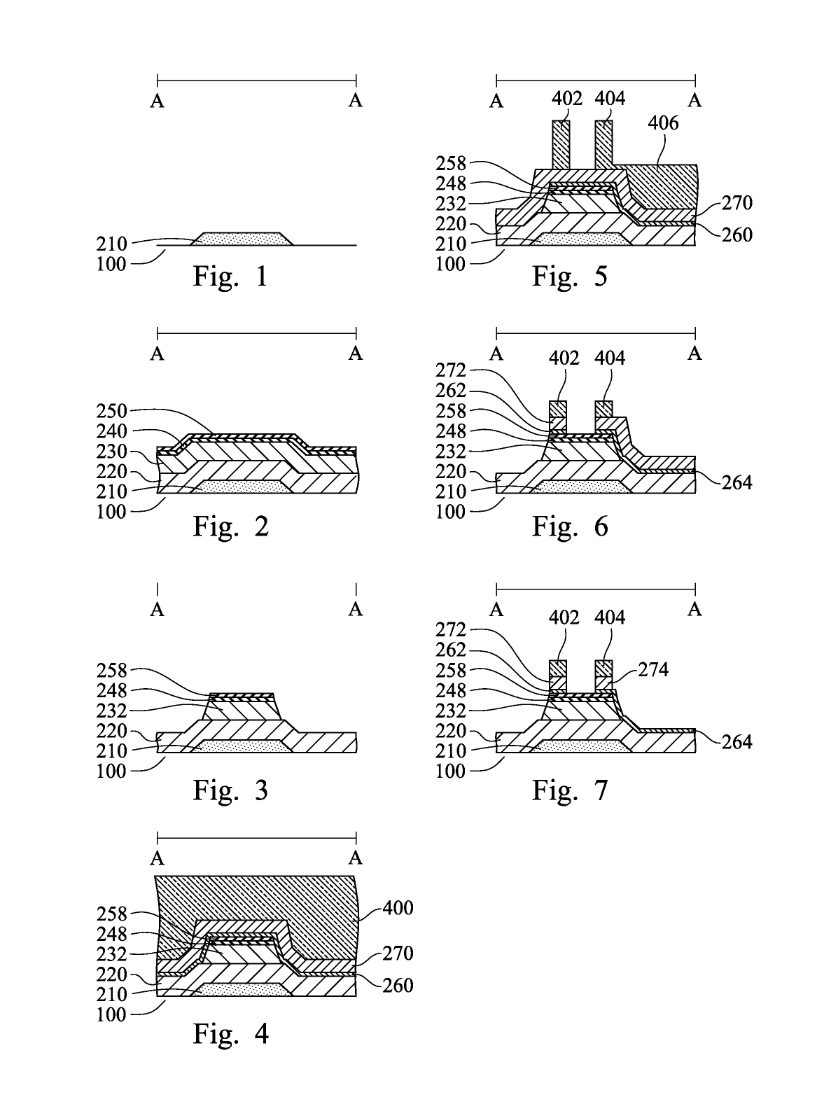

FIGS. 1 to 9 illustrate sectional views of the manufacturing process of a pixel structure according to the first embodiment of the present invention. FIG. 10 illustrates a top schematic view of a pixel structure according to the first embodiment of the present invention. FIGS. 1 to 9 are sectional views along the line segment A-A in FIG. 10. The design in the top schematic view of the pixel structure of the present invention is designed only for illustrative purposes and is not limited to the above-mentioned drawings, a person having ordinary skills in the art may appropriately modify the design according to the requirements.

Please first refer to FIG. 1. As shown in the figure, the manufacturer can at this stage first form a gate electrode 210 on a substrate 100, for example, first forming a conductive layer, followed by lithography and etching to pattern the conductive layer, thereby forming the gate electrode 210 on the substrate 100. In the present embodiment, the material for the substrate 100 may be silicon, the conductive layer may be a single layer or a multi-layer structure, and the material can be a metal or metal compound. The metal material includes titanium, molybdenum, chromium, iridium, aluminum, copper, silver, gold, zinc, indium, gallium or the combination thereof. And the metal compound material includes metal alloy, metal oxide, metal nitride, metal oxynitride or the combination thereof. The patterning method of the conductive layer may be a deposition, lithography and etching, screen printing, inkjet or laser ablation method.

Next, please refer to FIG. 2. As shown in the figure, the manufacturer can at this stage sequentially form a gate dielectric layer 220, a silicon semiconductor layer 230, a silicon ohmic contact layer 240 and an auxiliary ohmic contact layer 250 covering the gate electrode 210 and the substrate 100. The materials for the gate dielectric layer 220 may be a single or multi-layer structure, and the material may be silicon nitride, silicon oxide, silicon oxynitride, or the combination thereof. The materials for the silicon semiconductor layer 230 may be amorphous silicon, microcrystalline silicon, polycrystalline silicon or epitaxial silicon. The materials for the silicon ohmic contact layer 240 are N-type doped silicon. The materials for the auxiliary ohmic contact layer 250 are metals.

Next, please refer to FIG. 3. As shown in the figure, the manufacturer can sequentially remove a portion of the auxiliary ohmic contact layer 250, silicon ohmic contact layer 240 and the silicon semiconductor layer 230 in FIG. 2, to form a patterned auxiliary ohmic contact layer 258, a patterned silicon ohmic contact layer 248 and a silicon channel layer 232 above the gate electrode 210. In the present embodiment, the auxiliary ohmic contact layer 250, the silicon ohmic contact layer 240 and the silicon semiconductor layer 230 may be removed by dry etching or wet etching.

Next, please refer to FIG. 4. As shown in the figure, the manufacturer can sequentially form a transparent conductive material layer 260 and a metal layer 270 covering the gate dielectric layer 220 and the patterned auxiliary ohmic contact layer 258. In the present embodiment, the materials for the transparent conductive material layer 260 can be indium tin oxide, indium zinc oxide, aluminum zinc oxide or the combination thereof. The metal layer 270 may be a single layer or a multi-layer structure, and the material may be a metal or a metal compound. The metal material includes titanium, molybdenum, chromium, iridium, aluminum, copper, silver, gold, zinc, indium, gallium or the combination thereof. And the metal compound material includes metal alloy, metal oxide, metal nitride, metal oxynitride or the combination thereof. Then, the manufacturer can form a photoresist layer 400 on the metal layer 270.

Next, please refer to FIG. 5. As shown in the figure, the manufacturer can use a halftone photomask process to pattern the photoresist layer 400 in FIG. 4 to form a patterned photoresist layer. The above-mentioned patterned photoresist layer may include two thick photoresist regions 402, 404 and a thin photoresist region 406. The thick photoresist regions 402 and 404 are each located above a part of the patterned auxiliary ohmic contact layer 258, the thin photoresist region 406 covers region M of FIG. 10. The photoresist layer 400 does not protect the other regions.

Next, please refer to FIG. 6. As shown in the figure, the manufacturer can at this stage use the patterned photoresist layer (including the thick photoresist regions 402, 404 and thin photoresist region 406) as a photomask to remove the exposed transparent conductive material layer 260 and metal layer 270 in FIG. 5, to pattern a part of the metal layer 270 underneath the thick photoresist region 402 as a source electrode 272, pattern a part of the transparent conductive material layer 260 underneath the thick photoresist region 402 as a transparent conductive portion 262, and pattern a part of the transparent conductive material layer 260 underneath the thick photoresist region 404 and thin photoresist region 406 as a transparent pixel electrode 264. In the present embodiment, the transparent conductive material layer 260 and the metal layer 270 may be removed by dry etching or wet etching.

Then, the manufacturer may at this stage remove parts of the photoresist layer. More specifically, the manufacturer can at this stage remove the thin photoresist region 406 in FIG. 5, while thinning the thick photoresist regions 402 and 404. In the present embodiment, an ashing process can be used to remove the thin photoresist region 406 and thin the thick photoresist regions 402 and 404.

Next, please refer to FIG. 7. As shown in the figure, the manufacturer can at this stage pattern the remaining photoresist layer (i.e., the thick photoresist regions 402 and 404 after thinning) as a photomask to remove parts of the metal layer 270 (as depicted in FIG. 5) to form a drain electrode 274 below the thick photoresist region 404, and expose a part of the transparent pixel electrode 264. In the present embodiment, the metal layer 270 may be removed by dry etching or wet etching.

One should note that although in the present embodiment, to reduce the amount of photomasks used, the processes in FIGS. 5-7 used a halftone photomask, but this does not limit the present invention, a person having ordinary skills in the art may also, according to the practical requirements, use a photomask manufacturing process to form the source electrode 272, the transparent conductive portion 262 and the transparent pixel electrode 264, and use another photomask manufacturing process to form a drain electrode 274 and expose the transparent pixel electrode 264.

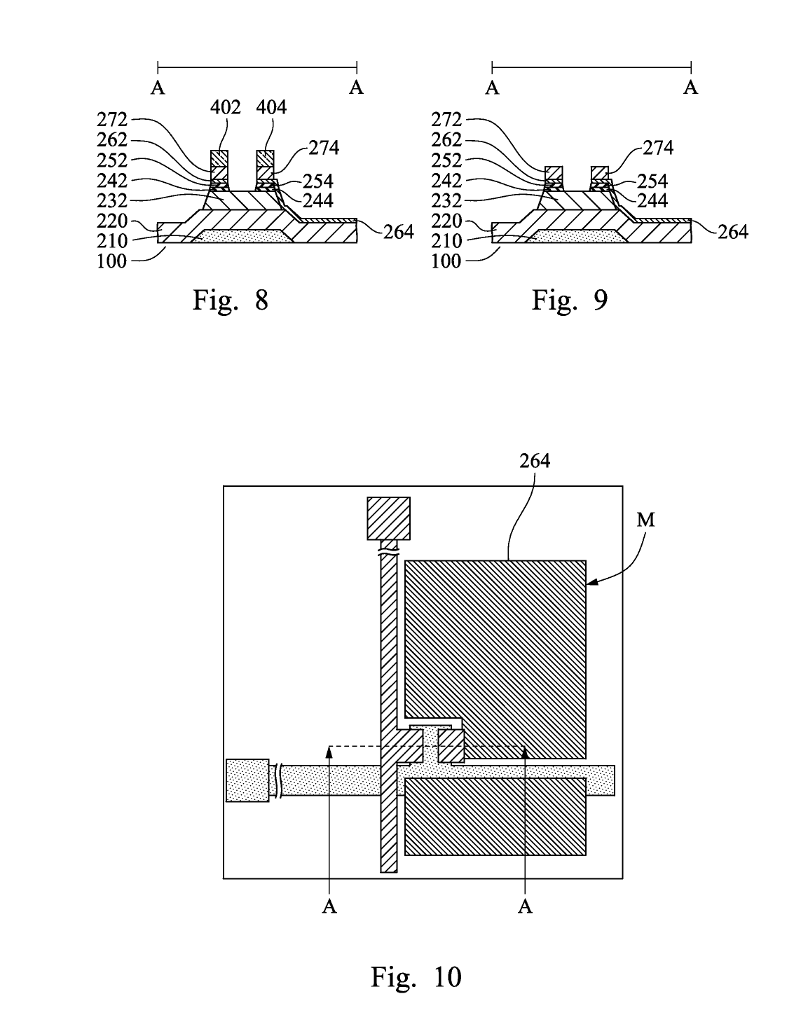

Next, please refer to FIG. 8. As shown in the figure, the manufacturer may then remove a part of the patterned auxiliary ohmic contact layer 258 in FIG. 7, to respectively form a source auxiliary ohmic contact layer 252 and a drain auxiliary ohmic contact layer 254 below the source electrode 272 and the drain electrode 274. In the present embodiment, parts of the patterned auxiliary ohmic contact layer 258 may be removed by dry etching or wet etching.

Next, the manufacturer may then remove a part of the patterned silicon ohmic contact layer 248 in FIG. 7, to respectively form a silicon source ohmic contact layer 242 and a silicon drain ohmic contact layer 244 below the source auxiliary ohmic contact layer 252 and the drain auxiliary ohmic contact layer 254. In the present embodiment, parts of the patterned silicon ohmic contact layer 248 may be removed by dry etching or wet etching.

Next, please refer to FIG. 9. As shown in the figure, the manufacturer can use a stripper to remove the remaining patterned photoresist layer (i.e., thick photoresist regions 402 and 404 after thinning, as depicted in FIG. 8). As a result, the manufacturing process of the pixel structure is complete.

From a structural point of view, the pixel structure is disposed on the substrate 100. The pixel structure includes a gate electrode 210, a gate dielectric layer 220, a silicon channel layer 232, a silicon source ohmic contact layer 242, a silicon drain ohmic contact layer 244, a source auxiliary ohmic contact layer 252, a drain auxiliary ohmic contact layer 254, a transparent conductive portion 262, a transparent pixel electrode 264, a source electrode 272 and a drain electrode 274. The gate electrode 210 is disposed on the substrate 100. The gate dielectric layer 220 covers the gate electrode 210 and the substrate 100. The silicon channel layer 232 is disposed on the gate dielectric layer 220, and disposed above the gate electrode 210. The silicon source ohmic contact layer 242 and silicon drain ohmic contact layer 244 are separately disposed on the silicon channel layer 232. The source auxiliary ohmic contact layer 252 and the drain auxiliary ohmic contact layer 254 are separately disposed on the silicon source ohmic contact layer 242 and silicon drain ohmic contact layer 244. The transparent conductive portion 262 is disposed on the source auxiliary ohmic contact layer 252. At least a portion of the transparent pixel electrode 264 is disposed on the drain auxiliary ohmic contact layer 254. The source electrode 272 is disposed on the transparent conductive portion 262. The drain electrode 274 is disposed on the transparent pixel electrode 264, and disposed above the drain auxiliary ohmic contact layer 254.

In this embodiment, a portion of the transparent pixel electrode 264 is disposed between the drain electrode 274 and the silicon channel layer 232, and the transparent pixel electrode 264 is directly electrically connected to the drain electrode 274, therefore a via structure to electrically connect the drain electrode 274 and the transparent pixel electrode 264 is no longer required, thus reducing the amount of photomask used. In addition, the drain auxiliary ohmic contact layer 254 can reduce the resistance between the silicon drain ohmic contact layer 244 and the transparent pixel electrode 264, thus giving good electrical connection between the silicon drain ohmic contact layer 244 and the transparent pixel electrode 264. The drain auxiliary ohmic contact layer 254 may be formed without the need of additional photomask processes, and therefore will not increase the cost of photomasks. Furthermore, in the present embodiment, the transparent pixel electrode 264 is disposed below the drain electrode 274, therefore a halftone photomask process can be used to reduce the amount of photomask used. As a result, the manufacturer can complete the manufacturing process of the pixel structure without significantly increasing the manufacturing cost.

### Second Embodiment

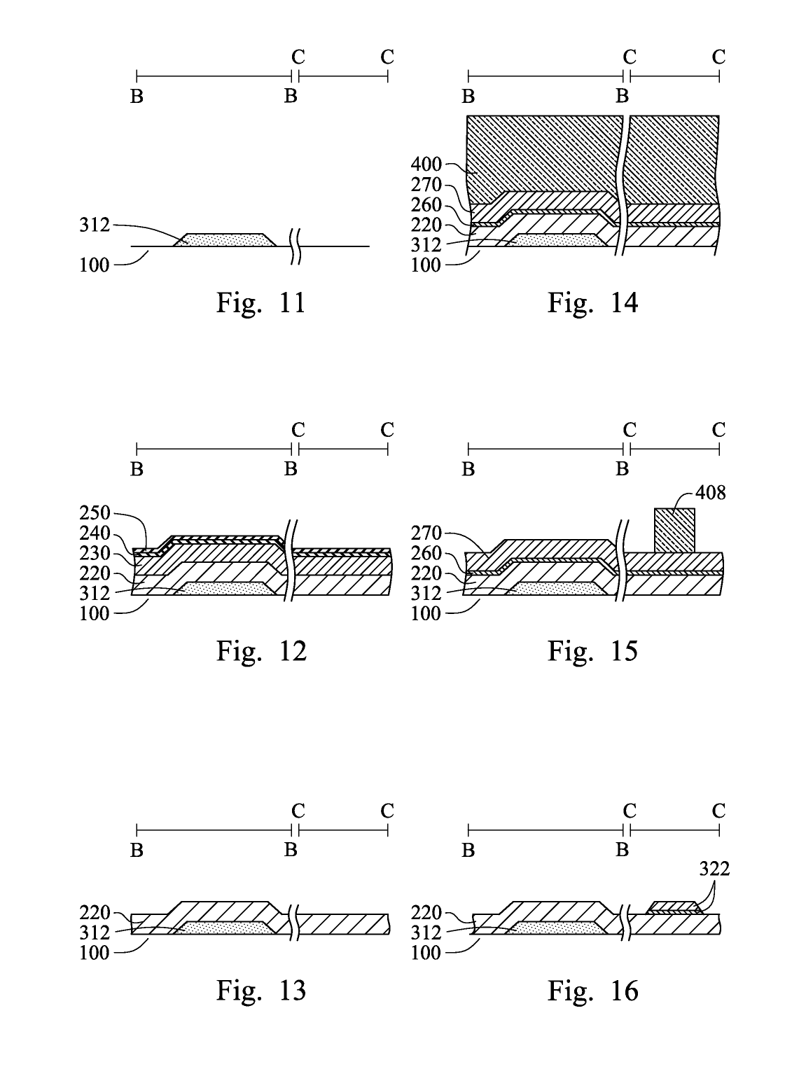

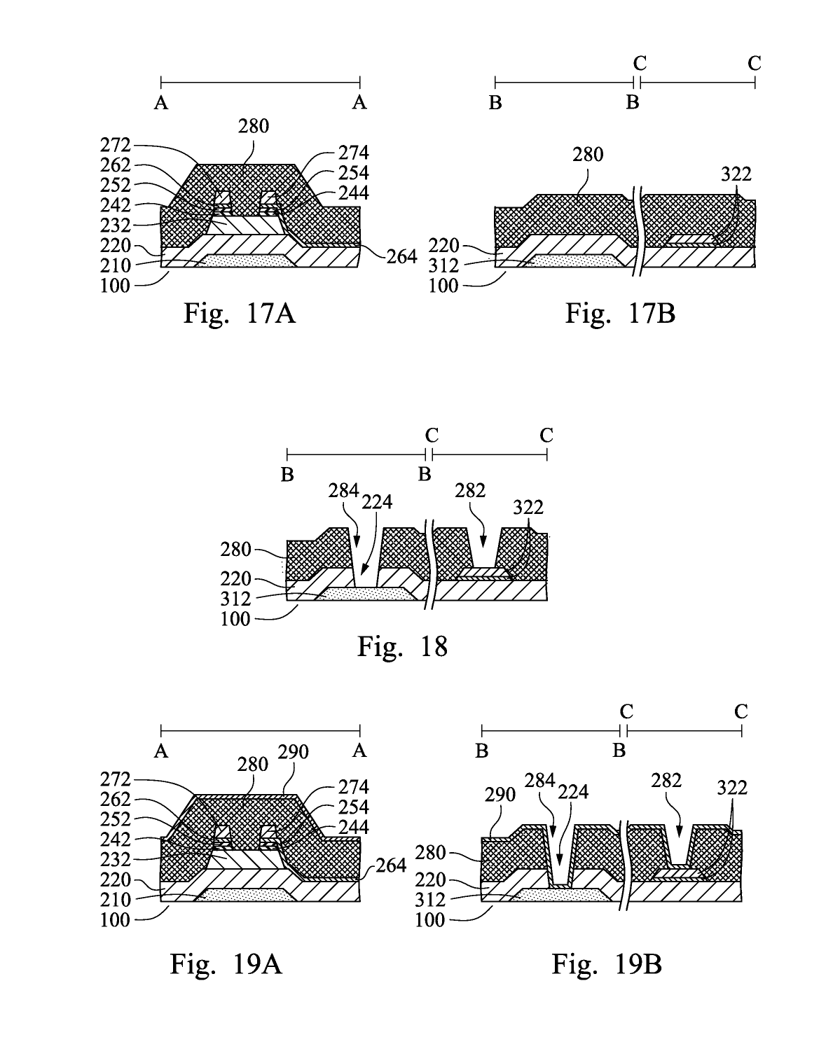

FIGS. 11 to 20 illustrate sectional view of the manufacturing process of a pixel structure according to the second embodiment of the present invention. FIG. 21 illustrates a top schematic view of a pixel structure according to the second embodiment of the present invention. Wherein FIGS. 11 to 16, 17B, 18, 19B and 20 are sectional views along the line segment B-B and C-C in FIG. 21; and FIGS. 17A, 19A and 20A are sectional views along the line segment A-A in FIG. 21. The design in the top schematic view of the pixel structure of the present invention is designed only for illustrative purposes and is not limited to the above-mentioned drawings, a person having ordinary skills in the art may appropriately modify the design according to the requirements. It should be noted that, the manufacturing steps of the A-A sectional view part in the present embodiment is the same as the first embodiment, therefore please also refer to FIGS. 1 to 9.

Please first refer to FIGS. 1 and 11 together. As shown in the figures, the manufacturer can at this stage first form a gate electrode 210, a gate line 310 (as depicted in FIG. 21) and a gate electrode pad 312 on a substrate 100, for example, first forming a conductive layer, followed by lithography and etching to pattern the conductive layer, thereby forming the gate electrode 210, the gate line 310 and the gate electrode pad 312 on the substrate 100. In the present embodiment, the material for the substrate 100 may be silicon, the conductive layer may be a single layer or a multi-layer structure, and the material can be a metal or metal compound. The metal material includes titanium, molybdenum, chromium, iridium, aluminum, copper, silver, gold, zinc, indium, gallium or the combination thereof. And the metal compound material includes metal alloy, metal oxide, metal nitride, metal oxynitride or the combination thereof. The patterning method of the conductive layer may be a deposition, lithography and etching, screen printing, inkjet or laser ablation method.

Next, please refer to FIGS. 2 and 12. As shown in the figures, the manufacturer can at this stage sequentially form a gate dielectric layer 220, a silicon semiconductor layer 230, a silicon ohmic contact layer 240 and an auxiliary ohmic contact layer 250 covering the gate electrode 210, the gate line 310, the gate electrode pad 312 and the substrate 100. The materials for the gate dielectric layer 220 may be a single or multi-layer structure, and the material may be silicon nitride, silicon oxide, silicon oxynitride or the combination thereof. The materials for the silicon semiconductor layer 230 may be amorphous silicon, microcrystalline silicon, polycrystalline silicon or epitaxial silicon. The materials for the silicon ohmic contact layer 240 may be N-type doped silicon. The materials for the auxiliary ohmic contact layer 250 may be metals.

Next, please refer to FIGS. 3 and 13. As shown in the figures, the manufacturer can sequentially remove parts of the auxiliary ohmic contact layer 250, silicon ohmic contact layer 240 and the silicon semiconductor layer 230 in FIGS. 2 and 12, to form a patterned auxiliary ohmic contact layer 258, patterned silicon ohmic contact layer 248 and the silicon channel layer 232 above the gate electrode 210. In the present embodiment, the auxiliary ohmic contact layer 250, the silicon ohmic contact layer 240 and the silicon semiconductor layer 230 may be removed by dry etching or wet etching.

Next, please refer to FIGS. 4 and 14. As shown in the figures, the manufacturer can sequentially form a transparent conductive material layer 260 and a metal layer 270 covering the gate dielectric layer 220 and the patterned auxiliary ohmic contact layer 258. In the present embodiment, the materials for the transparent conductive material layer 260 can be indium tin oxide, indium zinc oxide, aluminum zinc oxide or any combination thereof. The metal layer 270 may be a single layer or a multi-layer structure, and the material may be a metal or a metal compound. The metal material includes titanium, molybdenum, chromium, iridium, aluminum, copper, silver, gold, zinc, indium, gallium or the combination thereof. And the metal compound material includes metal alloy, metal oxide, metal nitride, metal oxynitride or the combination thereof. Then, the manufacturer can form a photoresist layer 400 on the metal layer 270.

Next, please refer to FIGS. 5 and 15. As shown in the figure, the manufacturer can use a halftone photomask process to pattern the photoresist layer 400 in FIGS. 4 and 14 to form a patterned photoresist layer. The above-mentioned patterned photoresist layer may include two thick photoresist regions 402, 404 and two thin photoresist regions 406, 408. The thick photoresist regions 402 and 404 are each located above a part of the patterned auxiliary ohmic contact layer 258, the thin photoresist region 406 covers region M of FIG. 21, and the thin photoresist region 408 covers region P of FIG. 21. The photoresist layer 400 does not protect the other regions.

Next, please refer to FIGS. 6 and 16. As shown in the figures, the manufacturer can at this stage pattern the photoresist layer (including the thick photoresist regions 402, 404 and thin photoresist regions 406, 408) as a photomask, to remove the exposed transparent conductive material layer 260 and metal layer 270 in FIGS. 5 and 15, to pattern a part of the metal layer 270 underneath the thick photoresist region 402 as a source electrode 272, pattern a part of the transparent conductive material layer 260 underneath the thick photoresist region 402 as a transparent conductive portion 262, pattern a part of the transparent conductive material layer 260 underneath the thick photoresist region 404 and thin photoresist region 406 as a transparent pixel electrode 264, and to altogether pattern a part of the transparent conductive material layer 260 and metal layer 270 underneath the thin photoresist region 408 as a data line 320 (as depicted in FIG. 21) and a data pad 322. In the present embodiment, the transparent conductive material layer 260 and the metal layer 270 may be removed by dry etching or wet etching.

Then, the manufacturer may at this stage remove parts of the photoresist layer. More specifically, the manufacturer can remove the thin photoresist regions 406 and 408 in FIGS. 5 and 15, while thinning the thick photoresist regions 402 and 404. In the present embodiment, an ashing process can be used to remove the thin photoresist regions 406 and 408 and thin the thick photoresist regions 402 and 404.

Next, please refer to FIG. 7. As shown in the figure, the manufacturer can at this stage use the remaining patterned photoresist layer (i.e., the thick photoresist regions 402 and 404 after thinning) as a photomask to remove parts of the metal layer 270 (as depicted in FIGS. 5 and 15) to form a drain electrode 274 below the thick photoresist region 404, and expose a part of the transparent pixel electrode 264. In the present embodiment, the metal layer 270 may be removed by dry etching or wet etching.

One should note that although in the present embodiment, to reduce the amount of photomasks used, the processes in FIGS. 5-7 and 15-16 used a halftone photomask, but this does not limit the present invention, a person having ordinary skills in the art may also, according to the practical requirements, use a photomask manufacturing process to form the source electrode 272, the transparent conductive portion 262, the transparent pixel electrode 264, the data line 320 (as depicted in FIG. 21) and the data pad 322, and use another photomask manufacturing process to form a drain electrode 274 and expose the transparent pixel electrode 264.

Next, please refer to FIG. 8. As shown in the figure, the manufacturer may then remove a part of the patterned auxiliary ohmic contact layer 258 in FIG. 7, to respectively form a source auxiliary ohmic contact layer 252 and a drain auxiliary ohmic contact layer 254 below the source electrode 272 and the drain electrode 274. In the present embodiment, parts of the patterned auxiliary ohmic contact layer 258 may be removed by dry etching or wet etching.

Next, the manufacturer may then remove a part of the patterned silicon ohmic contact layer 248 in FIG. 7, to respectively form a silicon source ohmic contact layer 242 and a silicon drain ohmic contact layer 244 below the source auxiliary ohmic contact layer 252 and the drain auxiliary ohmic contact layer 254. In the present embodiment, parts of the patterned silicon ohmic contact layer 248 may be removed by dry etching or wet etching.

Next, please refer to FIG. 9. As shown in the figure, the manufacturer can use a stripper to remove the remaining patterned photoresist layer (i.e., the thick photoresist regions 402 and 404 after thinning, as depicted in FIG. 8).

Next, please refer to FIGS. 17A and 17B. As shown in the figures, the manufacturer can at this stage form a passivation layer 280 to at least cover the source electrode 272, drain electrode 274, silicon channel layer 232, transparent pixel electrode 264, data line 320 (as depicted in FIG. 21) and data pad 322. In this embodiment, the material for the passivation layer 280 may be silicon nitride, silicon oxide, silicon oxynitride, or any combination thereof.

Next, please refer to FIG. 18. As shown in the figure, the manufacturer can form a first contact hole 282 in the passivation layer 280 to at least expose a part of the data pad 322, and form a second contact hole 284 in the passivation layer 280, and form a third contact hole 224 in the gate dielectric layer 220, the second contact hole 284 and the third contact hole 224 together expose at least a portion of the gate electrode pad 312. In the present embodiment, the first contact hole 282, the second contact hole 284 and the third contact hole 224 may be formed by lithography and etching.

Next, please refer to FIGS. 19A and 19B. As shown in the figures, the manufacturer can at this stage form an electrode layer 290 on the passivation layer 280, and the electrode layer 290 is electrically connected to the data pad 322 through the first contact hole 282, and electrically connected to the gate electrode pad 312 through the second contact hole 284 and the third contact hole 224. In the present embodiment, the materials for the electrode layer 290 may be indium tin oxide, indium zinc oxide, aluminum zinc oxide, or the combination thereof.

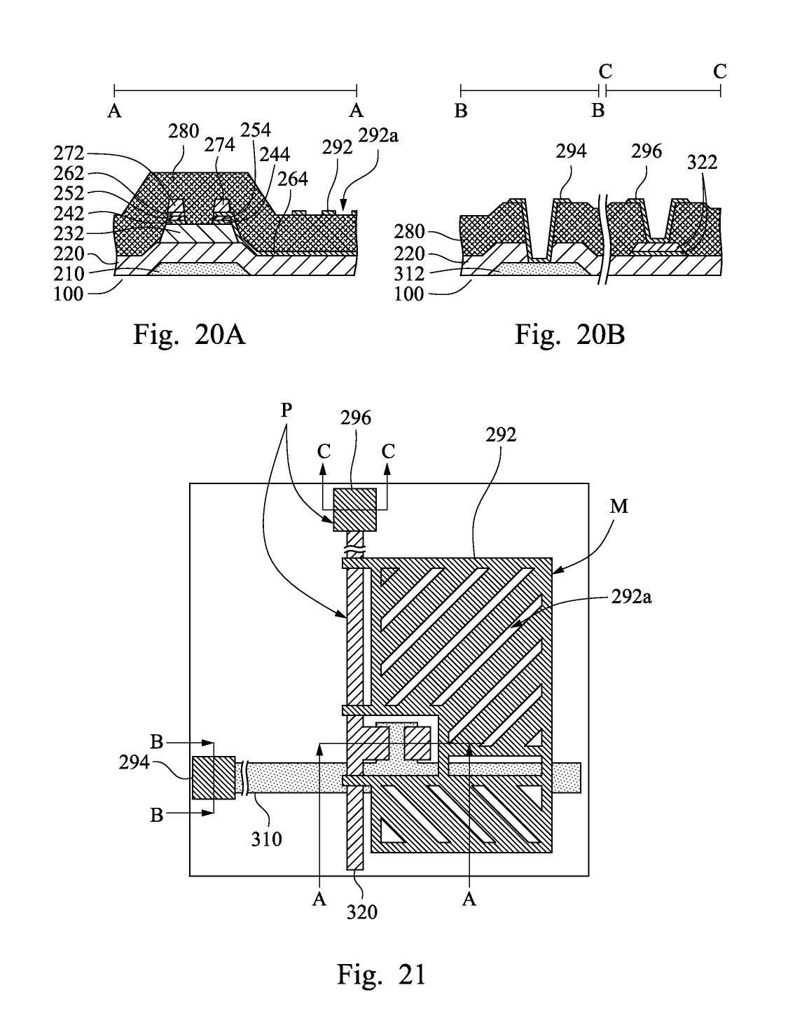

Next, please refer to FIGS. 20A and 20B. As shown in the figures, the manufacturer can at this stage pattern the electrode layer 290 in FIGS. 19A and 19B to form a common electrode 292 above the transparent pixel electrode 264, form a gate electrode contact pad 294 above the gate electrode pad 312, and form a data contact pad 296 above the data pad 322. Moreover, the manufacturer may form a plurality of openings 292a in the common electrode 292. In the present embodiment, the electrode layer 290 may be patterned by dry etching or wet etching. As a result, the manufacturing process of the pixel structure is complete.

From a structural point of view, the pixel structure is disposed on the substrate 100. The pixel structure includes a gate electrode 210, a gate dielectric layer 220, a silicon channel layer 232, a silicon source ohmic contact layer 242, a silicon drain ohmic contact layer 244, a source auxiliary ohmic contact layer 252, a drain auxiliary ohmic contact layer 254, a transparent conductive portion 262, a transparent pixel electrode 264, a source electrode 272, a drain electrode 274 and a common electrode 292. The gate electrode 210 is disposed on the substrate 100. The gate dielectric layer 220 covers the gate electrode 210 and the substrate 100. The silicon channel layer 232 is disposed on the gate dielectric layer 220, and disposed above the gate electrode 210. The silicon source ohmic contact layer 242 and silicon drain ohmic contact layer 244 are separately disposed on the silicon channel layer 232. The source auxiliary ohmic contact layer 252 and the drain auxiliary ohmic contact layer 254 are separately disposed on the silicon source ohmic contact layer 242 and silicon drain ohmic contact layer 244. The transparent conductive portion 262 is disposed on the source auxiliary ohmic contact layer 252. At least a portion of the transparent pixel electrode 264 is disposed on the drain auxiliary ohmic contact layer 254. The source electrode 272 is disposed on the transparent conductive portion 262. The drain electrode 274 is disposed on the transparent the pixel electrode 264, and disposed above the drain auxiliary ohmic contact layer 254. The common electrode 292 is disposed on the substrate 100, the common electrode 292 overlaps with the transparent pixel electrode 264, and the common electrode 292 has a plurality of openings 292a.

More specifically, the common electrode 292 is disposed above the transparent pixel electrode 264, and the pixel structure can further include a passivation layer 280, disposed between the common electrode 292 and the transparent pixel electrode 264. Moreover, the pixel structure can further include a gate line 310, a gate electrode pad 312, a data line 320, a data pad 322, a gate electrode contact pad 294 and a data contact pad 296. The gate line 310 and the gate electrode pad 312 is disposed between the substrate 100 and the gate dielectric layer 220, and the data line 320 and the data pad 322 is disposed between the gate dielectric layer 220 and the passivation layer 280, and the data line 320 and the data pad 322 are both electrically connected to the source electrode 272. The passivation layer 280 has a first contact hole 282 to expose parts of data pad 322, the data contact pad 296 is electrically connected to the data pad 322 through the first contact hole 282. The data contact pad 296 can protect the data pad 322, and can electrically connect to an external circuit. The passivation layer 280 further includes a second contact hole 284, and the gate dielectric layer 220 has a third contact hole 224. The second contact hole 284 and the third contact hole 224 together expose a portion of the gate electrode pad 312, the gate electrode contact pad 294 is electrically connected to the gate electrode pad 312 through the second contact hole 284 and the third contact hole 224. The gate electrode contact pad 294 can protect the gate electrode pad 312, and electrically connect to an external circuit.

In this embodiment, a portion of the transparent pixel electrode 264 is disposed between the drain electrode 274 and the silicon channel layer 232, and the transparent pixel electrode 264 is directly electrically connected to the drain electrode 274, therefore a via structure to electrically connect the drain electrode 274 and the transparent pixel electrode 264 is no longer required, thus reducing the amount of photomask used. In addition, the drain auxiliary ohmic contact layer 254 can reduce the resistance between the silicon drain ohmic contact layer 244 and the transparent pixel electrode 264, thus giving good electrical connection between the silicon drain ohmic contact layer 244 and the transparent pixel electrode 264. The drain auxiliary ohmic contact layer 254 may be formed without the need of additional photomask processes, and therefore will not increase the cost of photomasks. Furthermore, in the present embodiment, the transparent pixel electrode 264 is disposed below the drain electrode 274, therefore a halftone photomask process can be used to reduce the amount of photomask used. As a result, the manufacturer can complete the manufacturing process of the pixel structure without significantly increasing the manufacturing cost. In addition, in this embodiment, the openings 292a of the common electrode 292 can be used to achieve the wide viewing angle requirement in a display panel, and the openings 292a may be simultaneously formed while patterning the electrode layer 290 in FIGS. 19A and 19B during the manufacturing process, and thus will not increase the amount of photomask used.

### Third Embodiment

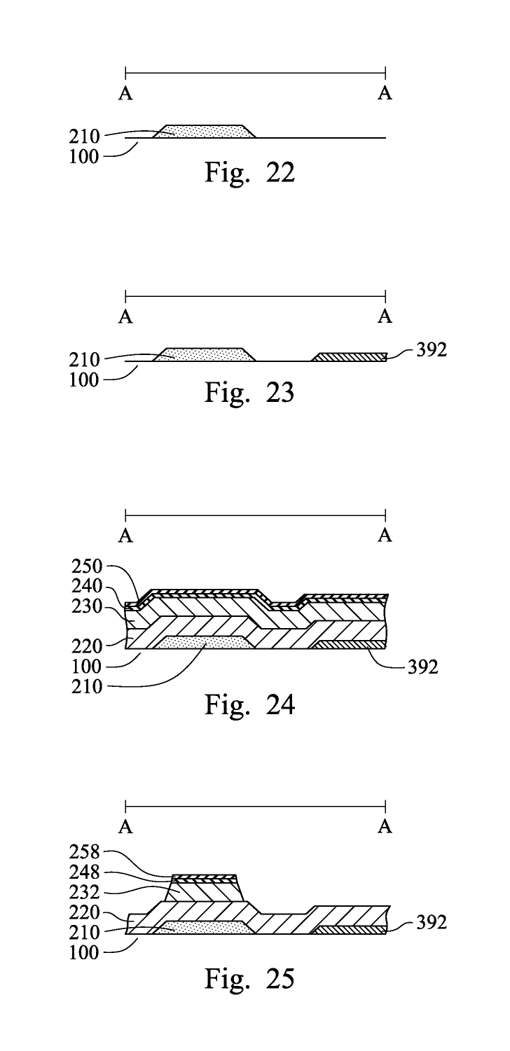

FIGS. 22 to 30 illustrate sectional views of the manufacturing process of a pixel structure according to the third embodiment of the present invention. FIG. 31 illustrates a top schematic view of a pixel structure according to the third embodiment of the present invention. FIGS. 22 to 30 are sectional views along the line segment A-A in FIG. 31. The design in the top schematic view of the pixel structure of the present invention is designed only for illustrative purposes and is not limited to the above-mentioned drawings, a person having ordinary skills in the art may appropriately modify the design according to the requirements.

Please first refer to FIG. 22. As shown in the figure, the manufacturer can at this stage first form a gate electrode 210 on the substrate 100, for example, first forming a conductive layer, followed by lithography and etching to pattern the conductive layer, thereby forming the gate electrode 210 on the substrate 100. In the present embodiment, the material for the substrate 100 may be silicon, the conductive layer may be a single layer or a multi-layer structure, and the material can be a metal or metal compound. The metal material includes titanium, molybdenum, chromium, iridium, aluminum, copper, silver, gold, zinc, indium, gallium or the combination thereof. And the metal compound material includes metal alloy, metal oxide, metal nitride, metal oxynitride or the combination thereof. The patterning method of the conductive layer may be a deposition, lithography and etching, screen printing, inkjet or laser ablation method.

Next, please refer to FIG. 23. As shown in the figure, the manufacturer can at this stage form a common electrode 392 on the substrate 100, for example, first forming an electrode layer, followed by lithography and etching to pattern the electrode layer, thereby forming the common electrode 392 on the substrate 100. In the present embodiment, the material for the electrode layer may be indium tin oxide, indium zinc oxide, aluminum zinc oxide, or the combination thereof.

Next, please refer to FIG. 24. As shown in the figure, the manufacturer can at this stage sequentially form a gate dielectric layer 220, a silicon semiconductor layer 230, a silicon ohmic contact layer 240 and an auxiliary ohmic contact layer 250 covering the gate electrode 210, common electrode 392 and the substrate 100. The materials for the gate dielectric layer 220 may be a single or multi-layer structure, and the material may be silicon nitride, silicon oxide, silicon oxynitride, or the combination thereof. The materials for the silicon semiconductor layer 230 may be amorphous silicon, microcrystalline silicon, polycrystalline silicon or epitaxial silicon. The materials for the silicon ohmic contact layer 240 are N-type doped silicon. The materials for the auxiliary ohmic contact layer 250 are metals.

Next, please refer to FIG. 25. As shown in the figure, the manufacturer can sequentially remove parts of the auxiliary ohmic contact layer 250, silicon ohmic contact layer 240 and the silicon semiconductor layer 230 in FIG. 24, to form a patterned auxiliary ohmic contact layer 258, a patterned silicon ohmic contact layer 248 and a silicon channel layer 232 above the gate electrode 210. In the present embodiment, the auxiliary ohmic contact layer 250, the silicon ohmic contact layer 240 and the silicon semiconductor layer 230 may be removed by dry etching or wet etching.

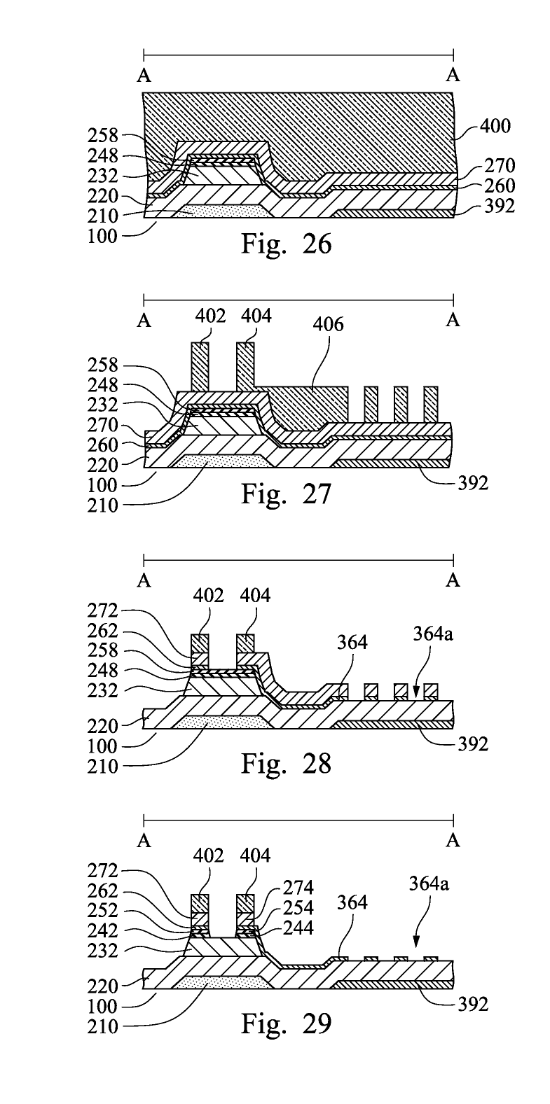

Next, please refer to FIG. 26. As shown in the figure, the manufacturer can sequentially form a transparent conductive material layer 260 and a metal layer 270 covering the gate dielectric layer 220 and the patterned auxiliary ohmic contact layer 258. In the present embodiment, the materials for the transparent conductive material layer 260 can be indium tin oxide, indium zinc oxide, aluminum zinc oxide or any combination thereof. The metal layer 270 may be a single layer or a multi-layer structure, and the material may be a metal or a metal compound. The metal material includes titanium, molybdenum, chromium, iridium, aluminum, copper, silver, gold, zinc, indium, gallium or the combination thereof. And the metal compound material includes metal alloy, metal oxide, metal nitride, metal oxynitride or the combination thereof. Afterwards, the manufacturer can form a photoresist layer 400 on the metal layer 270.

Next, please refer to FIG. 27. As shown in the figure, the manufacturer can use a halftone photomask process to pattern the photoresist layer 400 in FIG. 26 to form a patterned photoresist layer. The above-mentioned patterned photoresist layer may include two thick photoresist regions 402, 404 and a plurality of thin photoresist regions 406. The thick photoresist regions 402 and 404 are each located above a part of the patterned auxiliary ohmic contact layer 258, the thin photoresist region 406 covers region M of FIG. 31. The photoresist layer 400 does not protect the other regions.

Next, please refer to FIG. 28. As shown in the figure, the manufacturer can at this stage use the patterned photoresist layer (including the thick photoresist regions 402, 404 and the thin photoresist region 406 in FIG. 27) as a photomask, to remove the exposed transparent conductive material layer 260 and metal layer 270, pattern a part of the metal layer 270 underneath the thick photoresist region 402 as a source electrode 272, pattern a part of the transparent conductive material layer 260 underneath the thick photoresist region 402 as a transparent conductive portion 262, and pattern a part of the transparent conductive material layer 260 underneath the thick photoresist region 404 and thin photoresist region 406 as a transparent pixel electrode 364, wherein the transparent pixel electrode 364 has a plurality of openings 364a. In the present embodiment, the transparent conductive material layer 260 and the metal layer 270 may be removed by dry etching or wet etching.

Then, the manufacturer may at this stage remove parts of the photoresist layer. More specifically, the manufacturer can remove the thin photoresist region 406 in FIG. 27, while thinning the thick photoresist regions 402 and 404. In the present embodiment, an ashing process can be used to remove the thin photoresist region 406 and thin the thick photoresist regions 402 and 404.

Next, please refer to FIG. 29. As shown in the figure, the manufacturer can at this stage pattern the remaining photoresist layer (i.e., the thick photoresist region 402 and 404 after thinning) as a photomask to remove parts of the metal layer 270 (as depicted in FIG. 27) to form a drain electrode 274 below the thick photoresist region 404, and expose a part of the transparent pixel electrode 364. In the present embodiment, the metal layer 270 may be removed by dry etching or wet etching.

One should note that although in the present embodiment, to reduce the amount of photomasks used, the processes in FIGS. 27-29 used a halftone photomask, but this does not limit the present invention, a person having ordinary skills in the art may also, according to the practical requirements, use a photomask manufacturing process to form the source electrode 272, the transparent conductive portion 262 and the transparent pixel electrode 364, and use another photomask manufacturing process to form a drain electrode 274 and expose the transparent pixel electrode 364.

Next, the manufacturer may then remove a part of the patterned auxiliary ohmic contact layer 258 in FIG. 28, to respectively form a source auxiliary ohmic contact layer 252 and a drain auxiliary ohmic contact layer 254 below the source electrode 272 and the drain electrode 274. In the present embodiment, parts of the patterned auxiliary ohmic contact layer 258 may be removed by dry etching or wet etching.

Next, the manufacturer may then remove a part of the patterned silicon ohmic contact layer 248 in FIG. 28, to respectively form a silicon source ohmic contact layer 242 and a silicon drain ohmic contact layer 244 below the source auxiliary ohmic contact layer 252 and the drain auxiliary ohmic contact layer 254. In the present embodiment, parts of the patterned silicon ohmic contact layer 248 may be removed by dry etching or wet etching.

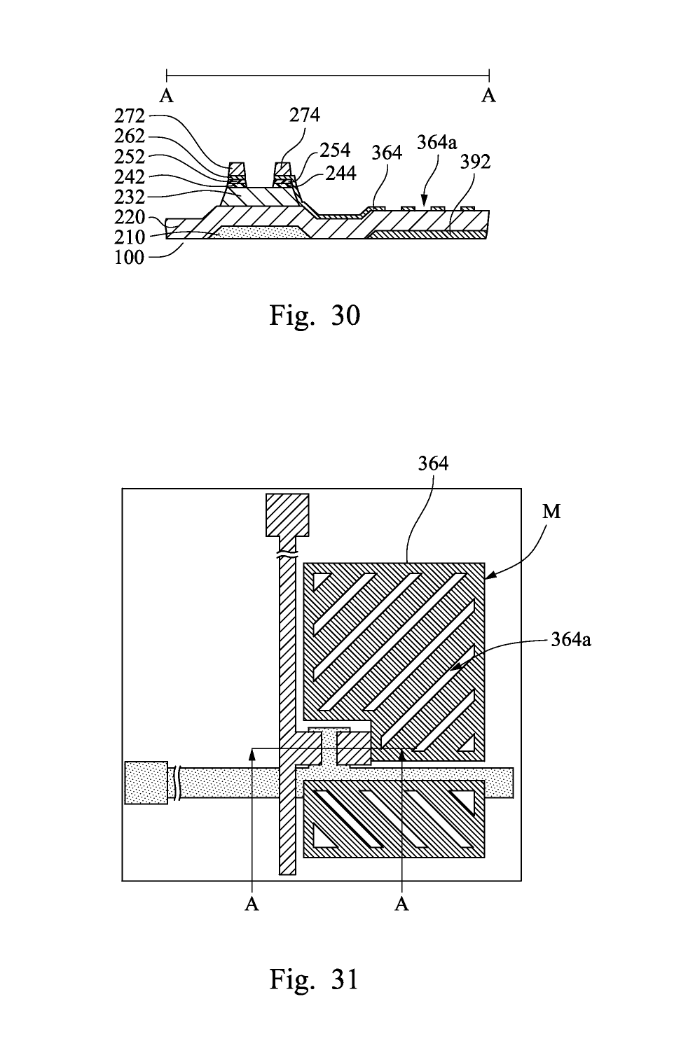

Next, please refer to FIG. 30. As shown in the figure, the manufacturer can use a stripper to remove the remaining patterned photoresist layer (i.e., thick photoresist region 402 and 404 after thinning, as depicted in FIG. 29). As a result, the manufacturing process of the pixel structure is complete.

From a structural point of view, the pixel structure is disposed on the substrate 100. The pixel structure includes a gate electrode 210, a gate dielectric layer 220, a silicon channel layer 232, a silicon source ohmic contact layer 242, a silicon drain ohmic contact layer 244, a source auxiliary ohmic contact layer 252, a drain auxiliary ohmic contact layer 254, a transparent conductive portion 262, a transparent pixel electrode 364, a source electrode 272, a drain electrode 274 and a common electrode 392. The gate electrode 210 is disposed on the substrate 100. The gate dielectric layer 220 covers the gate electrode 210 and the substrate 100. The silicon channel layer 232 is disposed on the gate dielectric layer 220, and disposed above the gate electrode 210. The silicon source ohmic contact layer 242 and silicon drain ohmic contact layer 244 are separately disposed on the silicon channel layer 232. The source auxiliary ohmic contact layer 252 and the drain auxiliary ohmic contact layer 254 are separately disposed on the silicon source ohmic contact layer 242 and silicon drain ohmic contact layer 244. The transparent conductive portion 262 is disposed on the source auxiliary ohmic contact layer 252. At least a portion of the transparent pixel electrode 364 is disposed on the drain auxiliary ohmic contact layer 254, and the transparent pixel electrode 364 has a plurality of openings 364a. The source electrode 272 is disposed on the transparent conductive portion 262. The drain electrode 274 is disposed on the transparent the pixel electrode 364, and disposed above the drain auxiliary ohmic contact layer 254. The common electrode 392 is disposed on the substrate 100, and the common electrode 392 and the transparent pixel electrode 364 overlap.

More specifically, the transparent pixel electrode 364 is disposed above the common electrode 392, and the gate dielectric layer 220 is disposed between the common electrode 392 and the transparent pixel electrode 364.

In this embodiment, a portion of the transparent pixel electrode 364 is disposed between the drain electrode 274 and the silicon channel layer 232, and the transparent pixel electrode 364 is directly electrically connected to the drain electrode 274, therefore a via structure to electrically connect the drain electrode 274 and the transparent pixel electrode 364 is no longer required, thus reducing the amount of photomask used. In addition, the drain auxiliary ohmic contact layer 254 can reduce the resistance between the silicon drain ohmic contact layer 244 and the transparent pixel electrode 364, thus giving good electrical connection between the silicon drain ohmic contact layer 244 and the transparent pixel electrode 364. The drain auxiliary ohmic contact layer 254 may be formed without the need of additional photomask processes, and therefore will not increase the cost of photomasks. Furthermore, in the present embodiment, the transparent pixel electrode 364 is disposed below the drain electrode 274, therefore a halftone photomask process can be used to reduce the amount of photomask used. As a result, the manufacturer can complete the manufacturing process of the pixel structure without significantly increasing the manufacturing cost. Furthermore, in the present embodiment, the openings 364a in the transparent pixel electrode 364 can be used to achieve the wide viewing angle requirement in a display panel, and the openings 364a may be simultaneously formed during the manufacturing process of forming the transparent pixel electrode 364, and thus will not increase the amount of photomask used.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A pixel structure disposed on a substrate, the pixel structure comprising:
a gate electrode disposed on the substrate;
a gate dielectric layer covering the gate electrode and the substrate;
a silicon channel layer disposed on the gate dielectric layer and above the gate electrode;
a silicon source ohmic contact layer and a silicon drain ohmic contact layer separately disposed on the silicon channel layer;
a source auxiliary ohmic contact layer and a drain auxiliary ohmic contact layer respectively disposed on the silicon source ohmic contact layer and the silicon drain ohmic contact layer;
a transparent conductive portion disposed on the source auxiliary ohmic contact layer;
a transparent pixel electrode in which at least a portion is disposed on the drain auxiliary ohmic contact layer;
a source electrode disposed on the transparent conductive portion; and
a drain electrode disposed on the transparent pixel electrode and above the drain auxiliary ohmic contact layer.

2. The pixel structure of claim 1, wherein a material of the source auxiliary ohmic contact layer and the drain auxiliary ohmic contact layer is metal.

3. The pixel structure of claim 1, wherein a material of the silicon channel layer is amorphous silicon, microcrystalline silicon, polycrystalline silicon or epitaxial silicon.

4. The pixel structure of claim 1, wherein a material of the silicon source ohmic contact layer and the silicon drain ohmic contact layer is N-type doped silicon.

5. The pixel structure of claim 1, further comprising:
a gate line disposed between the substrate and the gate dielectric layer and electrically connected to the gate electrode; and
a data line disposed on the gate dielectric layer and electrically connected to the source electrode.

6. The pixel structure of claim 1, further comprising:
a passivation layer covering at least the source electrode, the drain electrode, the silicon channel layer and the transparent pixel electrode; and
a common electrode disposed on the passivation layer and overlapping the transparent pixel electrode, wherein the common electrode have a plurality of openings.

7. The pixel structure of claim 1, further comprising a common electrode disposed between the substrate and the gate dielectric layer, and disposed beneath and overlapping the transparent pixel electrode.

8. The pixel structure of claim 7, wherein the transparent pixel electrode have a plurality of openings.

9. A pixel structure disposed on a substrate, the pixel structure comprising:
a gate electrode disposed on the substrate;
a gate dielectric layer covering the gate electrode and the substrate;
a silicon channel layer disposed on the gate dielectric layer and disposed above the gate electrode;
a silicon source ohmic contact layer and a silicon drain ohmic contact layer separately disposed on the silicon channel layer;
a source auxiliary ohmic contact layer and a drain auxiliary ohmic contact layer respectively disposed on the silicon source ohmic contact layer and the silicon drain ohmic contact layer;
a transparent conductive portion disposed on the source auxiliary ohmic contact layer;
a transparent pixel electrode in which at least a portion is disposed on the drain auxiliary ohmic contact layer;
a source electrode disposed on the transparent conductive portion;
a drain electrode disposed on the transparent pixel electrode and above the drain auxiliary ohmic contact layer; and
a common electrode disposed on the substrate and overlapping the transparent pixel electrode.

10. A method of manufacturing a pixel structure, comprising:
forming a gate electrode on a substrate;
sequentially forming a gate dielectric layer, a silicon semiconductor layer, a silicon ohmic contact layer and an auxiliary ohmic contact layer covering the gate electrode and the substrate;
sequentially removing a part of the auxiliary ohmic contact layer, the silicon ohmic contact layer and the silicon semiconductor layer to form a patterned auxiliary ohmic contact layer, a patterned silicon ohmic contact layer and a silicon channel layer above the gate electrode;
sequentially forming a transparent conductive material layer and a metal layer covering the gate dielectric layer and the patterned auxiliary ohmic contact layer;
removing a portion of the metal layer to respectively form a source electrode and a drain electrode separated from each other above the patterned auxiliary ohmic contact layer, and removing a portion of the transparent conductive material layer to form a transparent pixel electrode and a transparent conductive portion separated from each another, at least a portion of the transparent pixel electrode is formed between the drain electrode and the patterned auxiliary ohmic contact layer, and the transparent conductive portion is formed between the source electrode and the patterned auxiliary ohmic contact layer;
removing a portion of the patterned auxiliary ohmic contact layer to respectively form a source auxiliary ohmic contact layer and a drain auxiliary ohmic contact layer below the source electrode and the drain electrode; and
removing a portion of the patterned silicon ohmic contact layer to respectively form a silicon source ohmic contact layer and a silicon drain ohmic contact layer below the source auxiliary ohmic contact layer and the drain auxiliary ohmic contact layer.

11. The method of manufacturing a pixel structure of claim 10, wherein removing a portion of the metal layer and the transparent conductive material layer comprises:
forming a photoresist layer covering the metal layer;
forming a patterned photoresist layer by using a halftone photomask manufacturing process to pattern the photoresist layer;
forming the source electrode, the transparent conductive portion and the transparent pixel electrode by using the patterned photoresist layer as a photomask and removing the exposed the metal layer and the exposed portion of the transparent conductive material layer beneath the metal layer;
removing another portion of the photoresist layer to expose another portion of the metal layer; and
forming the drain electrode and exposing the transparent pixel electrode by using the remaining the patterned photoresist layer as a photomask to remove another portion of the metal layer.

12. The method of manufacturing a pixel structure of claim 10, wherein the material of the auxiliary ohmic contact layer is metal.

13. The method of manufacturing a pixel structure of claim 10, wherein the material of the silicon ohmic contact layer is N-type doped silicon.

14. The method of manufacturing a pixel structure of claim 10, further comprising:
forming a gate line between the substrate and the gate dielectric layer; and
forming a data line on the gate dielectric layer.

15. The method of manufacturing a pixel structure of claim 10, further comprising:
forming a gate electrode pad between the substrate and the gate dielectric layer;
forming a data pad on the gate dielectric layer;
forming a passivation layer to cover at least the source electrode, the drain electrode, the silicon channel layer, the transparent pixel electrode and the data pad;
forming a first contact hole in the passivation layer to expose at least a portion of the data pad;
forming a second contact hole in the passivation layer, and forming a third contact hole in the gate dielectric layer, the second contact hole and the third contact hole together expose at least a portion of the gate electrode pad;
forming an electrode layer on the passivation layer, wherein the electrode layer is electrically connected to the data pad through the first contact hole, electrically connected to the gate electrode pad through the second contact hole and the third contact hole; and
patterning the electrode layer to form a common electrode above the transparent pixel electrode, forming a gate electrode contact pad above the gate electrode pad, and forming a data contact pad above the data pad.

16. The method of manufacturing a pixel structure of claim 15, wherein patterning the electrode layer further comprises forming a plurality of openings in the common electrode.

17. The method of manufacturing a pixel structure of claim 10, further comprising forming a common electrode between the substrate and the gate dielectric layer.

18. The method of manufacturing a pixel structure of claim 17, further comprising forming a plurality of openings in the transparent pixel electrode.
